(19) United States
(12) Patent Application Publication
(10) Pub. No.: US 2023/0198670 A1
(43) Pub. Date: Jun. 22, 2023

(54) METHOD AND APPARATUS FOR POINT-TO-MULTI-POINT COMMUNICATIONS USING COMBINED BLOCK AND CODEWORD INTERLEAVING

(71) Applicant: Intel Corporation, Santa Clara, CA (US)

(72) Inventors: Rainer STROBEL, Muenchen (DE); Gert SCHEDELBECK, Muenchen (DE); Vladimir OKSMAN, Morganville, NJ (US); Ravindra SINGH, Bangalore (IN)

(21) Appl. No.: 17/995,928

(22) PCT Filed: May 10, 2021
(86) PCT No.: PCT/US2021/031475

§ 371 Date: Oct. 11, 2022

Related U.S. Application Data
(60) Provisional application No. 63/022,604, filed on May 11, 2020.

(51) Int. Cl. H04L 1/00

(52) U.S. Cl. CPC H04L 1/0071; H04L 1/0057; H04L 1/0059

(57) ABSTRACT

A method and apparatus for point-to-multi-point communications. A transmitter of a network device may include forward error correction (FEC) encoder configured to encode input data to generate a plurality of codewords, and an interleaver configured to perform a combined processing of block or convolutional interleaving and codeword interleaving on the plurality of codewords to generate one or more interleaving blocks. Each codeword belongs to one of a plurality of codeword groups associated with the plurality of subscriber-side devices and codewords belonging to different codeword groups are interleaved in each interleaving block. An FEC encoder in a subscriber-side device may encode input data to generate a plurality of codewords and an interleaver may perform interleaving on one or more of the plurality of codewords to generate one or more interleaving blocks, wherein an interleaving depth may be dynamically selected based on a burst length of upstream transmission.

### FIELD

Examples relate to communication in passive optical networks, more particularly a method and apparatus for point-to-multi-point communications using combined block and codeword interleaving.

### BACKGROUND

Data rates in a passive optical network (PON) have increased, e.g., to 25 Gbit/s or 50 Gbit/s per wavelength. With an increasing transmission speed, the quality of signal transmission could be deteriorated. In order to keep the required coverage distances of communication, this can be mitigated by improved forward error correction (FEC) coding and digital equalization.

Soft decision FEC coding such as low-density parity check (LDPC) codes are considered for the next generation PON transmissions. LDPC codes can operate close to channel capacity and hardware-friendly encoder and decoder implementations for the LDPC code exist.

### BRIEF DESCRIPTION OF THE FIGURES

Some examples of apparatuses and/or methods will be described in the following by way of example only, and with reference to the accompanying figures, in which

FIG. 1A is a block diagram of a network device in accordance with one example;

FIG. 1B is a block diagram of a subscriber-side device in accordance with one example;

FIG. 2 shows downstream transmission in a PON;

FIG. 3 shows an example PON frame for downstream with codeword interleaving;

FIG. 4 shows an example hard decision receiver;

FIG. 5 shows an example soft decision receiver;

FIG. 6A shows probability distribution of the number of errors per codeword;

FIG. 6B shows probability of a number of consecutive uncorrelated and correlated errors, respectively;

FIG. 7 shows an example of combined interleaving scheme in accordance with one example;

FIG. 8 shows an example combined block (or convolutional) and codeword interleaving where the number of subscriber groups do not match the interleaving depth;

FIG. 9 shows an example combined codeword and block interleaving with a frame header 910 as a part of the first interleaving block;

FIG. 10 shows a combined codeword and block interleaving with a frame header as part of the first interleaving block and the codewords;

FIGS. 11-12 are flow diagrams of a process for point-to-multi-point communications in accordance with some examples; and

FIG. 13 is a flow diagram of a process for decoding using the knowledge about correlated errors in accordance with one example.

### DETAILED DESCRIPTION

Various examples will now be described more fully with reference to the accompanying drawings in which some examples are illustrated. In the figures, the thicknesses of lines, layers and/or regions may be exaggerated for clarity.

Accordingly, while further examples are capable of various modifications and alternative forms, some particular examples thereof are shown in the figures and will subsequently be described in detail. However, this detailed description does not limit further examples to the particular forms described. Further examples may cover all modifications, equivalents, and alternatives falling within the scope of the disclosure. Like numbers refer to like or similar elements throughout the description of the figures, which may be implemented identically or in modified form when compared to one another while providing for the same or a similar functionality.

It will be understood that when an element is referred to as being “connected” or “coupled” to another element, the elements may be directly connected or coupled or via one or more intervening elements. If two elements A and B are combined using an “or”, this is to be understood to disclose all possible combinations, i.e. only A, only B as well as A and B. An alternative wording for the same combinations is “at least one of A and B”. The same applies for combinations of more than 2 elements.

The terminology used herein for the purpose of describing particular examples is not intended to be limiting for further examples. Whenever a singular form such as “a,” “an” and “the” is used and using only a single element is neither explicitly or implicitly defined as being mandatory, further examples may also use plural elements to implement the same functionality. Likewise, when a functionality is subsequently described as being implemented using multiple elements, further examples may implement the same functionality using a single element or processing entity. It will be further understood that the terms “comprises,” “comprising,” “includes” and/or “including,” when used, specify the presence of the stated features, integers, steps, operations, processes, acts, elements and/or components, but do not preclude the presence or addition of one or more other features, integers, steps, operations, processes, acts, elements, components and/or any group thereof.

Unless otherwise defined, all terms (including technical and scientific terms) are used herein in their ordinary meaning of the art to which the examples belong.

Examples are disclosed for combining block interleaving (or convolutional interleaving or any other interleaving scheme) and codeword interleaving into one interleaving step for PON downstream transmissions. This scheme can reduce the correlated errors and complexity of the receiver. Examples are also disclosed for block interleaving in upstream transmissions. Examples are also disclosed for using the knowledge of correlated errors in soft decoding in a receiver.

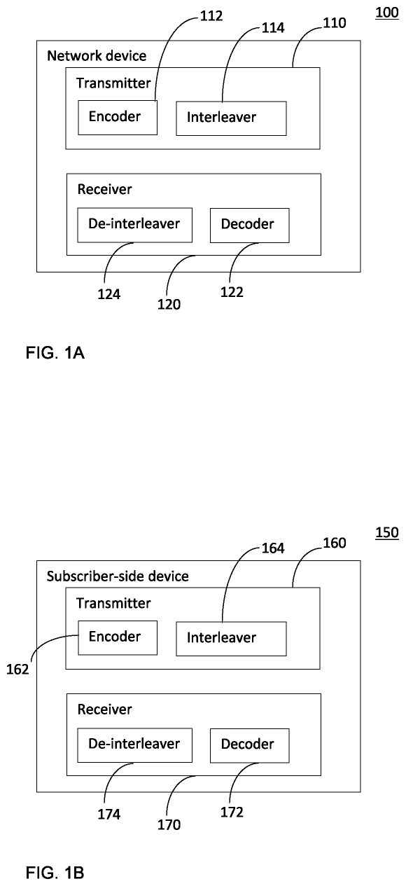

FIG. 1A is a block diagram of a network device (e.g., optical line termination (OLT)) in accordance with one example. The network device 100 may be connected to a plurality of subscriber-side devices (e.g., optical network units (ONUs)) in a point-to-multi-point communication system.

The network device 100 includes a transmitter 110 and a receiver 120. The transmitter 110 is configured to transmit a transmission frame to a plurality of subscriber-side devices. The transmitter 110 includes a forward error correction (FEC) encoder 112 and an interleaver 114. The FEC encoder 112 is configured to encode input data to generate a plurality of codewords for transmission to the plurality of subscriber-side devices 150. An FEC coding is a technique used for controlling errors in data transmission over unreliable or noisy communication channels. A transmitter encodes a message in a redundant way to allow a receiver to detect and correct a certain number of errors. An output of the FEC encoder 112 is called a codeword. The FEC code may be a block code such as LDPC code or any other FEC codes.

The interleaver 114 performs interleaving on the codewords that are output from the FEC encoder 112. Interleaving is a technique for making FEC more robust with respect to burst errors. Burst errors are errors that occur in many consecutive bits. The interleaver 114 at the transmitter 110 re-arranges the order of the input data stream to randomize the burst errors in a received data stream. At the receiver 120, the decoder 122 and the de-interleaver 124 perform the inverse of the encoding and interleaving operations, respectively, to recover the original data stream.

In examples, the interleaver 114 is configured to perform a combined processing of block (or convolutional) interleaving and codeword interleaving on the plurality of codewords to generate one or more interleaving blocks. An interleaving block is a block of data output from the interleaver 114. A block interleaver receives coded bits in blocks from an encoder and shuffles the bits. The shuffling is accomplished by writing the columns of an M×N array with encoded sequence and reading the rows from the array. A convolutional interleaver comprises a set of shift registers, each with a fixed delay. Each new input bit from the input signal feeds into the next shift register and the oldest symbol in that register becomes part of the output signal.

The transmitter 110 is configured to generate the transmission frame based on the interleaving blocks. Each codeword belongs to one of a plurality of codeword groups (subscriber groups) that are associated with a plurality of subscriber-side devices. In examples, codewords belonging to different codeword groups are interleaved in each interleaving block.

The number of the plurality of codeword groups may be the same as an interleaving depth, and each interleaving block contains bits from the same number of codewords as the interleaving depth. The interleaving depth (the depth of an interleaver) is the minimum separation in symbol periods at the output of the interleaver between any two symbols that were adjacent at the input of the interleaver. In another example, the number of the plurality of codeword groups may be less than the interleaving depth, and each interleaving block may contain bits from two or more codewords from the same codeword group. In another example, the number of the plurality of codeword groups may be greater than the interleaving depth, and each interleaving block may contain bits from a subset of the plurality of codeword groups. The bits of each codeword may be equidistantly spread over time in each interleaving block.

The transmitter 110 generates the transmission frame based on the interleaving blocks. A frame header is added to the transmission frame. In one example, the frame header may not be a part of the interleaving blocks and placed in advance of the interleaving blocks. Alternatively, the frame header of the transmission frame may be part of a first interleaving block but may be not part of codewords of the first interleaving block (i.e., may be not protected by the FEC code). Alternatively, the frame header of the transmission frame may be part of codewords of the first interleaving block and protected by the FEC code. The bits of the frame header may be part of systematic bits of the codewords so that the frame header bits may be recovered without FEC decoding. The frame header may include a physical synchronization block and overhead channel bits including a superframe counter. In some example, the overhead channel bits may be repeated for each codeword group. The transmitter may be configured to use different FEC settings for codewords for a hard decision receiver and codewords for a soft decision receiver.

In the examples, FEC codewords of the same codeword group or FEC codewords belonging to different codeword groups may be interleaved in each interleaving block. This type of interleaving can resolve the issue of correlated errors. Since a receiver in the PON system only decodes the FEC codewords of the subscriber group which the receiver belongs to, the decoder complexity can be reduced. A receiver may be associated with one or multiple codeword groups. The bit positions in the transmission for a certain codeword group (subscriber group) are known to the receivers in advance. Therefore, a receiver in downstream is not required to have memory of the size of the complete interleaving depth. Memory is required only for the bits of codewords of the subscriber group of the receiver.

FIG. 1B is a block diagram of a subscriber-side device in accordance with one example. The subscriber-side device 150 (e.g., ONU) includes a transmitter 160 and a receiver 170. The transmitter 160 is configured to transmit a transmission frame to the network device 100. The transmitter 160 includes an FEC encoder 162 and an interleaver 164. The FEC encoder 162 is configured to encode input data to generate a plurality of codewords for transmission to the network device 100. The FEC code may be a block code such as LDPC code or any other FEC codes.

The interleaver 164 performs interleaving on the codewords that are output from the FEC encoder 162. At the receiver 170, the decoder 172 and the de-interleaver 174 perform the inverse of the encoding and interleaving operations, respectively, to recover the original data stream.

The transmitter 160 of the subscriber-side device 150 transmits a transmission frame to a network device 100. The FEC encoder 162 may be configured to encode input data to generate a plurality of codewords. The interleaver 164 may be configured to perform interleaving on one or more of the plurality of codewords to generate one or more interleaving blocks. The transmitter 160 may be configured to dynamically select an interleaving depth based on a burst length of the upstream transmission to the network device 100. If the burst length is shorter than an FEC codeword, the transmitter 160 may apply shortening to the codewords. Shortening means that some of the payload bits are not transmitted, which decreases the code rate. In some examples, the interleaving depth, an FEC code rate, and/or an FEC block size may be determined by the network device 100 and communicated to the subscriber-side device 150.

In an upstream direction, block interleaving is applied to match the size of the burst up to a certain maximum interleaving depth for larger bursts. In case where the length of the burst is less than the required interleaving depth to achieve the target bit error rate, the code rate of the FEC code may be reduced, e.g., by shortening to achieve the required output bit error rate.

An FEC decoder 122 in the receiver 120 or 172 in the receiver 170 is configured to decode codewords received from a transmitter. In some examples, the FEC decoder 122, 172 may be configured to identify bit error positions on a first codeword by comparing inputs and outputs of the FEC decoder 122, 172 and adjust soft information for decoding subsequent codewords based on the bit error positions. The FEC decoder 122, 172 may be configured to reduce log-likelihood ratio (LLR) absolute for bit positions close to the bit error positions and increase the LLR absolute for bit positions remote from the bit error positions.

The examples disclosed herein can effectively improve performance of forward error correction coding in the presence of correlated errors and allow to reduce complexity at the point-to-multipoint receiver at the same time by partitioning the data stream into multiple groups.

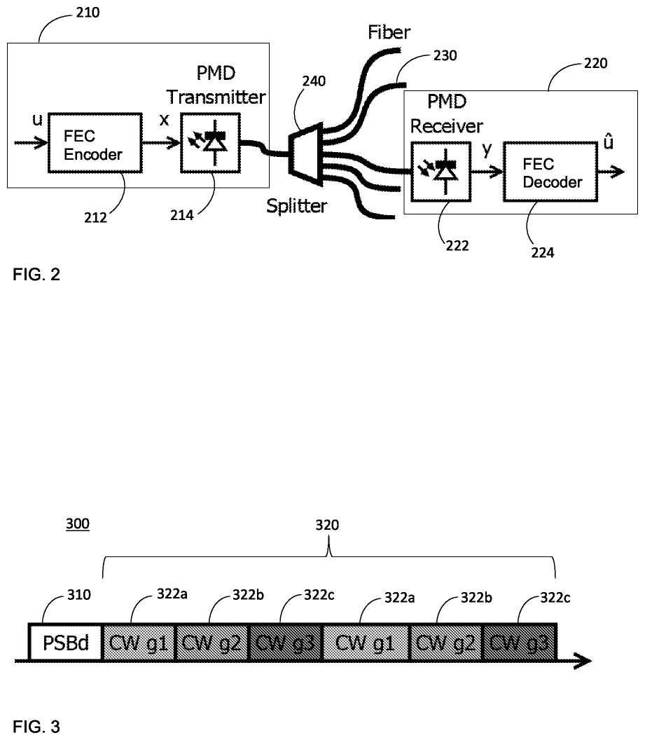

FIG. 2 shows downstream transmission in a PON. A PON is a point-to-multipoint transmission system including a central node, e.g., an optical line termination (OLT) 210 (i.e., corresponding to a network device 100) and multiple optical network units (ONUs) 220 at the subscriber side (i.e., corresponding to a subscriber-side device 150). The central node (e.g., the OLT 210) and the ONUs 220 are connected via optic cables 230 and passive optical splitters 240. In downstream, data is transmitted from the central node (the OLT 210) to the ONUs 220 and in upstream, data is transmitted from the ONUs 220 to the central node.

For downstream transmissions, the incoming data is encoded by an FEC encoder 212 (e.g., an LDPC encoder) in the OLT 210 and converted to an optical signal by a physical media-dependent layer (PMD) transmitter 214. In the ONU 220, the PMD receiver 222 converts the incoming optical signals to electrical signals and the FEC decoder 224 (e.g., LDPC decoder) recovers the transmitted bit stream.

An LDPC code is a kind of FEC code. An LDPC code is a block code, where K incoming payload bits are processed in one step and R parity bits are added. The LDPC codeword includes N=K+R bits, where N is a codeword size. To adjust the code rate (the ratio between the payload bits (K) and the codeword size (N)) and to optimize the code performance, the LDPC code can be shortened by S bits or punctured by P bits. Shortening means that some of the payload bits are not transmitted, which decreases the code rate. Puncturing means that some of the parity bits are not transmitted, which increases the code rate. The code rate (CR) after shortening and puncturing is: CR=(K−S)/(N−S−P). One LDPC codeword in downstream direction may contain payload bits associated with (intended to be received by) different ONUs.

With an increasing transmission speed, the probability of correlated errors increases due to dispersion and limited receiver bandwidth and digital equalization, which may introduce burst errors. This is the case for both hard decision and soft decision receiver architectures. Burst errors can cause performance degradation of FEC codes such as LDPC codes. To achieve a good performance of the FEC coding, the effect of correlated errors should be minimized.

As the LDPC decoder contributes significantly to the receiver complexity and thus to the receiver power consumption for a higher speed PON, reducing the amount of data processed by the downstream receiver LDPC decoder can save power and complexity, especially when taking into account that a PON is a point-to-multipoint system and the majority of data processed by the LDPC decoder is not relevant for an individual optical network unit (ONU).

Codeword interleaving is one way to reduce the amount of data to be processed by the receiver LDPC decoder in a PON system and to reduce complexity of the PON downstream receiver. For codeword interleaving, the transmit data stream is partitioned into multiple groups of complete codewords (e.g., LDPC codewords) and each PON downstream receiver (i.e., ONU 220) is assigned to receive one or multiple codeword groups. With the codeword interleaving scheme the receiver at the ONU knows in advance which of the LDPC codewords are relevant for the receiver, and the receiver may then decode only the codewords intended for the receiver. With this scheme, each downstream receiver can receive and decode only the corresponding codewords, which reduces the complexity at the receiver.

FIG. 3 shows an example PON frame 300 for downstream with codeword interleaving. The PON frame 300 for downstream includes a downstream physical synchronization block (PSBd) 310 and a payload 320. The PSBd 310 facilitates synchronization in the ONUs. The payload 320 comprises codewords intended for one or more ONUs. In this example, the transmit data stream is partitioned into three groups and the codewords 322a-322c in three groups are interleaved in time in a PON frame 300. Conventionally, no interleaving is applied between different codewords (within the subscriber group or belonging to different subscriber groups) and thus, correlated errors can degrade the performance of the LDPC code.

In the upstream direction, codeword interleaving is not practical because upstream transmissions are organized in bursts per ONU. The issue of correlated errors is present in upstream as well and even more severe as the error probability can be higher at the start of the burst due to convergence of the timing recovery and digital equalizers. An additional issue to be addressed in the upstream is short bursts with a length around one FEC codeword. In this case, block interleaving cannot be used to improve the coding gain and a code rate may be reduced.

To improve the performance in the presence of correlated errors in a PON, Omega-256 interleaving may be used together with an LDPC code. However, the Omega-256 interleaver works on small 256-bit blocks of bits and gives a very limited performance improvement.

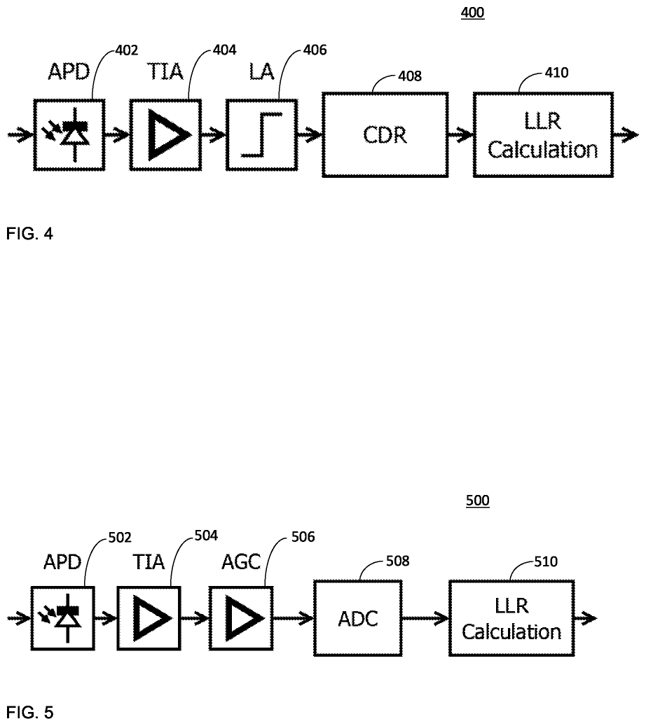

Receivers may use hard decision or soft decision for decoding the received data. FIG. 4 shows an example hard decision receiver 400. A hard decision receiver 400 has a lower complexity and uses hard decision hard input. The optical signal is converted into an electrical current signal by a photo diode 402 (e.g., an avalanche photo diode (APD), etc.). A transimpedance amplifier (TIA) 404 amplifies the current signal from the photo diode 402 and converts to a voltage signal. The receiver 400 may include a limiting amplifier (LA) 406 to further amplify the voltage signal and convert to a digital signal. The clock-data recovery (CDR) circuit 408 extracts a clock signal and re-times the data signal. The log-likelihood ratio (LLR) calculation block 410 generates the input signal for the decoder (e.g., LDPC decoder).

A higher coding gain may be achieved with a soft decision receiver. FIG. 5 shows an example soft decision receiver 500. The optical signal is converted into an electrical current signal by a photo diode 502 (e.g., an APD). A TIA 504 amplifies the current signal from the photo diode 502 and converts to a voltage signal. The voltage signal may be amplified with an automatic gain control (AGC) 506 to a constant level and then converted to a digital signal by an analog-to-digital converter (ADC) 508. An LLR calculation block 510 may use the amplitude information to derive the input signal (soft bits) for the decoder.

The PMD components (e.g., APD 402+TIA 404+LA 406, or APD 502+TIA 506+AGC 508) may be part of an optics module. Subsequent components, from the CDR 408 or the ADC 508 onwards may be part of a digital transceiver device.

A higher speed PON may use hard decision receiver architectures, as they are used for 25G PON. However, for 50 Gbit/s or a higher transmission speed, soft input receivers based on ADC and digital equalization can provide significant improvements.

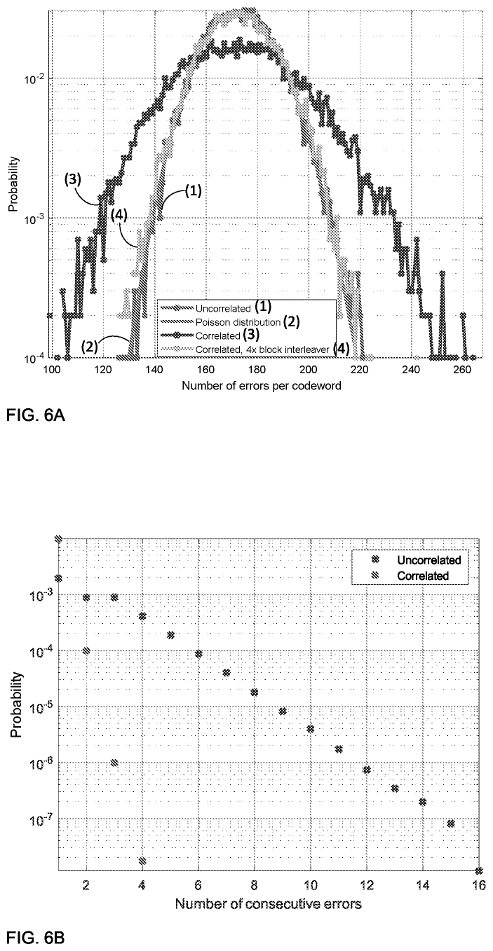

For a hard decision receiver, correlated errors can be observed in the probability that multiple consecutive bit errors occur. For uncorrelated errors, the probability of n consecutive errors is approximately BERG, where BER stands for bit error rate, while in presence of correlated errors, the probability of consecutive errors may be much higher. This is shown in FIGS. 6A and 6B as an example. FIG. 6A shows probability distribution of the number of errors per codeword. FIG. 6B shows probability of a number of consecutive uncorrelated and correlated errors, respectively.

This effect itself may not be an issue for block codes like LDPC codes. The performance degradation for a block code will result from the probability of a certain number of errors per codeword, as shown in FIG. 6A. However, comparison of the correlated error channel with the uncorrelated error channel of the same raw bit error rate shows that in the correlated error channel there are more codewords with a large number of errors and more codewords with a small number of errors per codeword than in case of uncorrelated errors, i.e., the probability of codewords with large number of errors increases. The increasing probability of codewords with a large number of errors causes the increased probability of FEC decoding failure and thus degraded error correction capabilities.

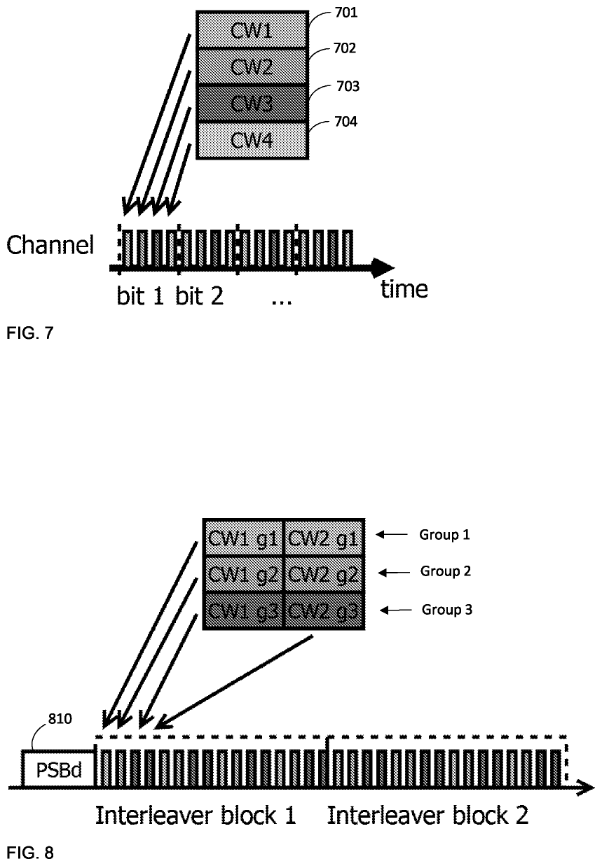

In examples, block interleaving (or convolutional interleaving) and codeword interleaving are combined. FIG. 7 shows an example of combined interleaving scheme in accordance with one example. For the combined block (or convolutional) and codeword interleaving, the transmission frame is partitioned into interleaving blocks. Each interleaving block contains codewords of multiple different codeword groups (subscriber groups). Each PON receiver (i.e., ONU) is assigned to receive one or multiple codeword groups. For the combined block (or convolutional) interleaving and codeword interleaving, codewords of a block code (e.g., LDPC code) belonging to multiple codeword groups (in this example, four codeword groups) are collected in a memory and the bits of the codewords are re-arranged such that the individual bits (or group of bits) of the codewords may be more or less equidistantly spread over time in an interleaving block. In the example shown in FIG. 7, the four groups of codewords 701-704 are multiplexed into an interleaving block such that the bits of each codeword 701-704 are equidistantly arranged in time (e.g., bit 1 from codeword 1, bit 1 from codeword 2, bit 1 from codeword 3, bit 1 from codeword 4, bit 2 from codeword 1, bit 2 from codeword 2, bit 2 from codeword 3, bit 2 from codeword 4, and so on). In this example, the interleaver outputs a bit from each codeword and then returns back. The interleaver spreads the bits of the multiple codewords comprising a PON frame over the time assigned for transmission of these codewords, i.e., not overlapping with the bits of the codewords comprising the next or previous PON frame.

The effect of the interleaver on the probability distribution of the number of errors per codeword is shown in FIG. 6A. The behaviour is improved significantly (see curve (4) in FIG. 6A) and thus, the performance of the FEC coding is close to the performance in case of uncorrelated errors.

The number of codeword groups (subscriber groups) may not match with the interleaving depth of the interleaver. In case when the number of subscriber groups is smaller than the interleaving depth (i.e., smaller than the number of codewords processed in the interleaver), multiple codewords from the same group are used in one interleaving block to keep the interleaving gain.

FIG. 8 shows an example combined block (or convolutional) and codeword interleaving where the number of subscriber groups do not match the interleaving depth. In this example, the number of subscriber groups in each interleaving block is three (3) and the interleaving depth is four (4), and the bits of two codewords from the subscriber group 3 is included in each interleaving block, (e.g., bit 1 from codeword 1 of group 1, bit 1 from codeword 1 of group 2, bit 1 from codeword 1 of group 3, bit 1 from codeword 2 of group 3, bit 2 from codeword 1 of group 1, bit 2 from codeword 1 of group 2, bit 2 from codeword 1 of group 3, bit 2 from codeword 2 of group 3, and so on).

Block interleaving, in general, requires large buffers at the transmitter and the receiver side to collect multiple codewords. In accordance with examples disclosed herein, the buffer size at the ONU receiver can be reduced, because only the bits of the codeword group of interest need to be stored and the bit positions are known in advance.

A transmission frame (a PON frame) starts with a header structure (e.g., a downstream physical synchronization block (PSBd)). The PSBd contains a known pattern for synchronization (physical synchronization pattern (Psync)) and an overhead channel (OC) including a superframe counter (SFC). In one example, the header structure (e.g., PSBd 810) may not be part of the interleaved codewords and may be placed in front of the codewords, as shown in FIG. 8.

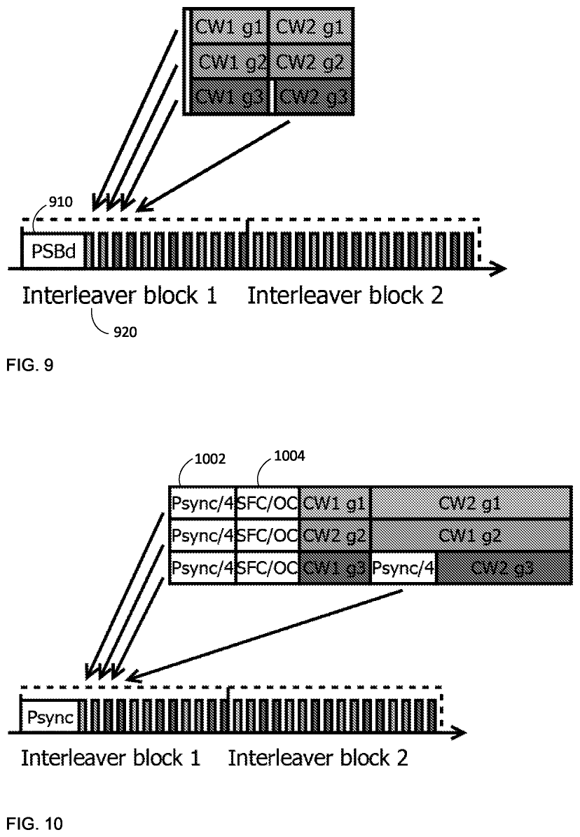

In another example, the first interleaving block is shortened by the length of the frame header, but the header is not protected by the block code (e.g., LDPC code). In this case, each individual codeword of the first interleaving block is shortened accordingly. FIG. 9 shows an example combined codeword and block interleaving with a frame header 910 as a part of the first interleaving block 920. As shown in FIG. 9, the PSBd 910 may be placed in front of the first interleaving block 920.

In another example, the frame header may be part of the codewords (e.g., LDPC codewords) and the frame header may be encoded (e.g., LDPC-protected). In this case, the frame header may be protected by different codewords. To achieve the full protection capability of the FEC for the header structure, all codewords may be decoded. When decoding only a subset of the codewords in the interleaving block, the error correction capability of the frame header may be reduced accordingly. To have the full FEC protection of the overhead channel part of the frame header, the overhead channel bits, which carry for example a superframe counter and transmission control bits, may be repeated according to the interleaving depth. This will give the full correction capabilities for the overhead channel even in case that only a part of the codewords are decoded. Repetitions may not be applied to the known synchronization pattern (Psync) of the frame header. The frame header may be part of the systematic part of the codeword such that the header can be decoded without the help of the FEC.

FIG. 10 shows a combined codeword and block interleaving with a frame header as part of the first interleaving block and the codewords. In this example, the synchronization pattern (Psync) 1002 is distributed among the codewords of the interleaving block and the overhead channel 1004 is repeated for each codeword.

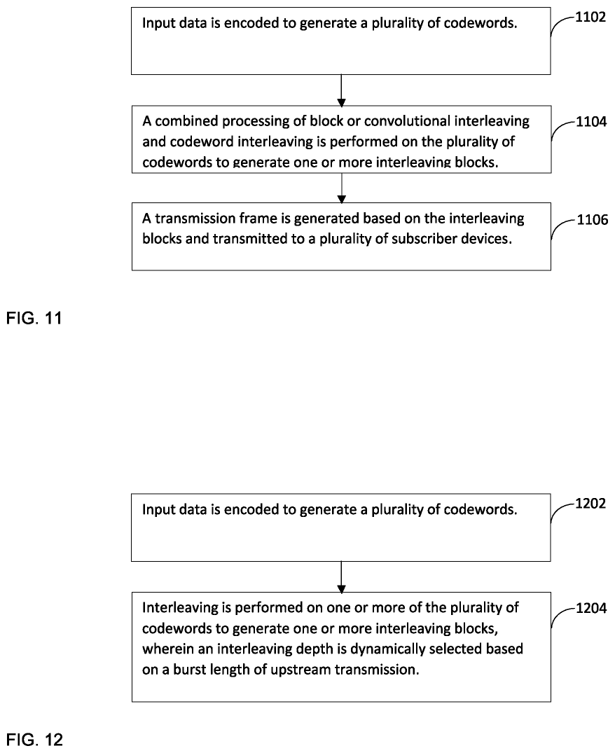

FIG. 11 is a flow diagram of a process for point-to-multi-point communications in accordance with one example. Input data is encoded to generate a plurality of codewords (1102). A combined processing of block or convolutional interleaving and codeword interleaving is performed on the plurality of codewords to generate one or more interleaving blocks (1104). A transmission frame is generated based on the interleaving blocks and transmitted to a plurality of subscriber-side devices (1106). Each codeword belongs to one of a plurality of codeword groups associated with the plurality of subscriber-side devices and codewords belonging to different codeword groups are interleaved in each interleaving block.

Correlated errors are present in upstream as well. In upstream, there is an additional effect of an increased error rate and decreased signal quality at the start of the upstream burst due to settling effects of timing recovery and equalizers. Thus, interleaving can improve the performance in upstream. A combination with codeword interleaving between different ONUS is not applicable as each upstream burst contains only data of the corresponding ONU. The issue to be resolved in upstream is the fact that the bursts can have very different length.

In one example, if the length of upstream bursts is shorter than the FEC codeword, shortening is applied to the FEC codeword, (i.e., not transmitting some of the payload bits of the codeword). In this case, the loss of coding gain due to the loss of interleaving is compensated by the increase of coding gain through the shortening. If the length of bursts is equal to or greater than the desired interleaving depth times the size of the FEC codeword, the full interleaving and FEC coding gain is present. If the length of bursts is in-between, (i.e., the burst sizes of roughly one codeword up to a number of codewords less than the interleaving depth), additional measures may be performed to keep the coding gain. In one example, the coding gain may be reduced (e.g., by shortening) such that the required coding gain is achieved. The required shortening for a certain coding gain depends on the decoder implementation. Therefore, in one example, the amount of shortening for a certain burst may be communicated from the OLT to the ONU together with other parameters describing the burst transmission, e.g., interleaving depth applied for the burst and the length of the burst.

FIG. 12 is a flow diagram of a process for point-to-multi-point communication in accordance with one example. Input data is encoded to generate a plurality of codewords (1202). Interleaving is performed on one or more of the plurality of codewords to generate one or more interleaving blocks, wherein an interleaving depth is dynamically selected based on a burst length of upstream transmission (1204).

In some examples, the knowledge about correlated errors may be used to support the decoding operation and benefit from the coding gain. This is mainly applicable to the upstream, where all codewords of the interleaving block are decoded. It is also applicable in downstream in case that the interleaving block contains multiple codewords of one ONU group.

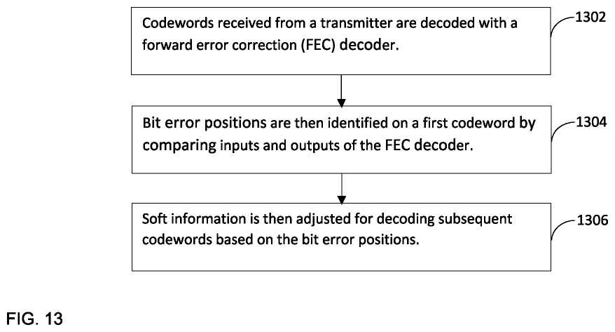

FIG. 13 is a flow diagram of a process for decoding using the knowledge about correlated errors in accordance with one example. Codewords received from a transmitter are decoded with a forward error correction (FEC) decoder (1302). Bit error positions are then identified on a first codeword by comparing inputs and outputs of the FEC decoder (1304). The first codeword is decoded, either completely or only with a reduced number of iterations to identify the positions of bit errors in the original received codeword by comparing the decoding output with the decoding input. Soft information is then adjusted for decoding subsequent codewords based on the bit error positions (1306). For example, with the known bit positions of the bit errors of the first codeword, the LLR values of the received bits close to the bit error positions may be reduced according to the probability of consecutive errors, which can be measured at the receiver side. For each of the following codewords to be decoded, this process may be repeated until all codewords of the interleaving block are decoded.

In case that the first codeword has not been decoded successfully, the decoding of the first codeword may be repeated with knowledge of the bit error positions from other codewords and the LLR values may be changed accordingly.

As a PON is a point-to-multipoint system, ONUs with different receiver architectures may be connected to the same OLT. Some ONUs may include a hard decision receiver and some ONUs may include a soft decision receiver. Codeword interleaving allows to have different FEC settings for different codeword groups, as long as the block size is the same or an integer multiple of the base line block size. In one example, codeword groups for hard decision receivers and codeword groups for soft decision receivers may use different FEC settings, optimized for the type of receiver.

Another example is a computer program having a program code for performing at least one of the methods described herein, when the computer program is executed on a computer, a processor, or a programmable hardware component. Another example is a machine-readable storage including machine readable instructions, when executed, to implement a method or realize an apparatus as described herein. A further example is a machine-readable medium including code, when executed, to cause a machine to perform any of the methods described herein.

The examples as described herein may be summarized as follows:

An example (e.g., example 1) relates to a network device for point-to-multi-point communications. The network device may include a transmitter configured to transmit a transmission frame to a plurality of subscriber-side devices. The transmitter may include an FEC encoder configured to encode input data to generate a plurality of codewords, and an interleaver configured to perform a combined processing of block or convolutional interleaving and codeword interleaving on the plurality of codewords to generate one or more interleaving blocks. The transmitter may be configured to generate the transmission frame based on the interleaving blocks. Each codeword belongs to one of a plurality of codeword groups associated with the plurality of subscriber-side devices and codewords belonging to different codeword groups are interleaved in each interleaving block.

Another example (e.g., example 2) relates to a previously described example (e.g., example 1), wherein the number of the plurality of codeword groups is same as an interleaving depth, and each interleaving block contains bits from the same number of codewords as the interleaving depth.

Another example (e.g., example 3) relates to a previously described example (e.g., example 1), wherein the number of the plurality of codeword groups is less than an interleaving depth, and each interleaving block contains bits from two or more codewords from a same codeword group.

Another example (e.g., example 4) relates to a previously described example (e.g., example 1), wherein the number of the plurality of codeword groups is greater than an interleaving depth, and each interleaving block contains bits from a subset of the plurality of codeword groups.

Another example (e.g., example 5) relates to a previously described example (e.g., one of examples 1-4), wherein bits of each codeword are equidistantly spread over time in each interleaving block.

Another example (e.g., example 6) relates to a previously described example (e.g., one of examples 1-5), wherein a frame header of the transmission frame is not part of the interleaving blocks and placed in advance of the interleaving blocks.

Another example (e.g., example 7) relates to a previously described example (e.g., one of examples 1-5), wherein a frame header of the transmission frame is part of a first interleaving block but is not part of codewords of the first interleaving block.

Another example (e.g., example 8) relates to a previously described example (e.g., one of examples 1-5), wherein a frame header of the transmission frame is part of codewords of the first interleaving block.

Another example (e.g., example 9) relates to a described example (e.g., example 8), wherein bits of the frame header are part of systematic bits of the codewords.

Another example (e.g., example 10) relates to a previously described example (e.g., one of examples 8-9), wherein the frame header includes a physical synchronization bits and overhead channel bits, and the overhead channel bits are repeated for each codeword group.

Another example (e.g., example 11) relates to a previously described example (e.g., one of examples 1-10), wherein the transmitter is configured to use different FEC settings for codewords for a hard decision receiver and codewords for a soft decision receiver.

Another example (e.g., example 12) relates to a device for a point-to-multi-point communication, comprising a transmitter for transmitting a transmission frame to a network device. The transmitter includes an FEC encoder configured to encode input data to generate a plurality of codewords and an interleaver configured to perform interleaving on one or more of the plurality of codewords to generate one or more interleaving blocks, wherein the transmitter is configured to dynamically select an interleaving depth based on a burst length of upstream transmission.

Another example (e.g., example 13) relates to a previously described example (e.g., example 12), wherein if the burst length is shorter than an FEC codeword, shortening is applied to the codewords.

Another example (e.g., example 14) relates to a previously described example (e.g., one of examples 12-13), wherein the interleaving depth, an FEC code rate, and an FEC block size are determined by the network device and communicated to the subscriber-side device.

Another example (e.g., example 15) relates to a receiver for a point-to-multi-point communication, comprising an FEC decoder configured to decode codewords received from a transmitter, wherein the FEC decoder is configured to identify bit error positions on a first codeword by comparing inputs and outputs of the FEC decoder and adjust soft information for decoding subsequent codewords based on the bit error positions.

Another example (e.g., example 16) relates to a previously described example (e.g., example 15), wherein the FEC decoder is configured to reduce log-likelihood ratio (LLR) absolute for bit positions close to the bit error positions and increase the LLR absolute for bit positions remote from the bit error positions.

Another example (e.g., example 17) relates to a method for point-to-multi-point communications. The method includes encoding input data to generate a plurality of codewords, performing a combined processing of block or convolutional interleaving and codeword interleaving on the plurality of codewords to generate one or more interleaving blocks, and generating a transmission frame based on the interleaving blocks and transmitting the transmission frame to a plurality of subscriber-side devices. Each codeword belongs to one of a plurality of codeword groups associated with the plurality of subscriber-side devices and codewords belonging to different codeword groups are interleaved in each interleaving block.

Another example (e.g., example 18) relates to a method for a point-to-multi-point communication, comprising encoding input data to generate a plurality of codewords, and performing interleaving on one or more of the plurality of codewords to generate one or more interleaving blocks, wherein an interleaving depth is dynamically selected based on a burst length of upstream transmission.

Another example (e.g., example 19) relates to a method for a point-to-multi-point communication, comprising decoding, with an FEC decoder, codewords received from a transmitter, identifying bit error positions on a first codeword by comparing inputs and outputs of the FEC decoder, and adjusting soft information for decoding subsequent codewords based on the bit error positions.

The aspects and features mentioned and described together with one or more of the previously detailed examples and figures, may as well be combined with one or more of the other examples in order to replace a like feature of the other example or in order to additionally introduce the feature to the other example.

Examples may further be or relate to a computer program having a program code for performing one or more of the above methods, when the computer program is executed on a computer or processor. Steps, operations or processes of various above-described methods may be performed by programmed computers or processors. Examples may also cover program storage devices such as digital data storage media, which are machine, processor or computer readable and encode machine-executable, processor-executable or computer-executable programs of instructions. The instructions perform or cause performing some or all of the acts of the above-described methods. The program storage devices may comprise or be, for instance, digital memories, magnetic storage media such as magnetic disks and magnetic tapes, hard drives, or optically readable digital data storage media. Further examples may also cover computers, processors or control units programmed to perform the acts of the above-described methods or (field) programmable logic arrays ((F)PLAs) or (field) programmable gate arrays ((F)PGAs), programmed to perform the acts of the above-described methods.

The description and drawings merely illustrate the principles of the disclosure. Furthermore, all examples recited herein are principally intended expressly to be only for pedagogical purposes to aid the reader in understanding the principles of the disclosure and the concepts contributed by the inventor(s) to furthering the art. All statements herein reciting principles, aspects, and examples of the disclosure, as well as specific examples thereof, are intended to encompass equivalents thereof.

A functional block denoted as “means for . . . ” performing a certain function may refer to a circuit that is configured to perform a certain function. Hence, a “means for s.th.” may be implemented as a “means configured to or suited for s.th.”, such as a device or a circuit configured to or suited for the respective task.

Functions of various elements shown in the figures, including any functional blocks labeled as “means”, “means for providing a sensor signal”, “means for generating a transmit signal.”, etc., may be implemented in the form of dedicated hardware, such as “a signal provider”, “a signal processing unit”, “a processor”, “a controller”, etc. as well as hardware capable of executing software in association with appropriate software. When provided by a processor, the functions may be provided by a single dedicated processor, by a single shared processor, or by a plurality of individual processors, some of which or all of which may be shared. However, the term “processor” or “controller” is by far not limited to hardware exclusively capable of executing software but may include digital signal processor (DSP) hardware, network processor, application specific integrated circuit (ASIC), field programmable gate array (FPGA), read only memory (ROM) for storing software, random access memory (RAM), and non-volatile storage. Other hardware, conventional and/or custom, may also be included.

A block diagram may, for instance, illustrate a high-level circuit diagram implementing the principles of the disclosure. Similarly, a flow chart, a flow diagram, a state transition diagram, a pseudo code, and the like may represent various processes, operations or steps, which may, for instance, be substantially represented in computer readable medium and so executed by a computer or processor, whether or not such computer or processor is explicitly shown. Methods disclosed in the specification or in the claims may be implemented by a device having means for performing each of the respective acts of these methods.

It is to be understood that the disclosure of multiple acts, processes, operations, steps or functions disclosed in the specification or claims may not be construed as to be within the specific order, unless explicitly or implicitly stated otherwise, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

Furthermore, the following claims are hereby incorporated into the detailed description, where each claim may stand on its own as a separate example. While each claim may stand on its own as a separate example, it is to be noted that—although a dependent claim may refer in the claims to a specific combination with one or more other claims—other examples may also include a combination of the dependent claim with the subject matter of each other dependent or independent claim. Such combinations are explicitly proposed herein unless it is stated that a specific combination is not intended. Furthermore, it is intended to include also features of a claim to any other independent claim even if this claim is not directly made dependent to the independent claim.

1. A network device for point-to-multi-point communications, comprising:
a transmitter configured to transmit a transmission frame to a plurality of subscriber-side devices, the transmitter including:
a forward error correction (FEC) encoder configured to encode input data to generate a plurality of codewords; and
an interleaver configured to perform a combined processing of block or convolutional interleaving and codeword interleaving on the plurality of codewords to generate one or more interleaving blocks;
wherein the transmitter is configured to generate the transmission frame based on the interleaving blocks,
wherein each codeword belongs to one of a plurality of codeword groups associated with the plurality of subscriber-side devices and codewords belonging to different codeword groups are interleaved in each interleaving block.

2. The network device of claim 1, wherein the number of the plurality of codeword groups is same as an interleaving depth, and each interleaving block contains bits from the same number of codewords as the interleaving depth.

3. The network device of claim 1, wherein the number of the plurality of codeword groups is less than an interleaving depth, and each interleaving block contains bits from two or more codewords from a same codeword group.

4. The network device of claim 1, wherein the number of the plurality of codeword groups is greater than an interleaving depth, and each interleaving block contains bits from a subset of the plurality of codeword groups.

5. The network device of claim 1, wherein bits of each codeword are equidistantly spread over time in each interleaving block.

6. The network device of claim 1, wherein a frame header of the transmission frame is not part of the interleaving blocks and placed in advance of the interleaving blocks.

7. The network device of claim 1, wherein a frame header of the transmission frame is part of a first interleaving block but is not part of codewords of the first interleaving block.

8. The network device of claim 1, wherein a frame header of the transmission frame is part of codewords of the first interleaving block.

9. The network device of claim 8, wherein bits of the frame header are part of systematic bits of the codewords.

10. The network device of claim 8, wherein the frame header includes a physical synchronization bits and overhead channel bits, and the overhead channel bits are repeated for each codeword group.

11. The network device of claim 1, wherein the transmitter is configured to use different FEC settings for codewords for a hard decision receiver and codewords for a soft decision receiver.

12. A device for a point-to-multi-point communication, comprising:
a transmitter for transmitting a transmission frame to a network device, the transmitter including:
a forward error correction (FEC) encoder configured to encode input data to generate a plurality of codewords; and
an interleaver configured to perform interleaving on one or more of the plurality of codewords to generate one or more interleaving blocks, wherein the transmitter is configured to dynamically select an interleaving depth based on a burst length of upstream transmission.

13. The device of claim 12, wherein if the burst length is shorter than an FEC codeword, shortening is applied to the codewords.

14. The device of claim 12, wherein the interleaving depth, an FEC code rate, and an FEC block size are determined by the network device and communicated to the subscriber-side device.

15. A receiver for a point-to-multi-point communication, comprising:
an FEC decoder configured to decode codewords received from a transmitter,
wherein the FEC decoder is configured to identify bit error positions on a first codeword by comparing inputs and outputs of the FEC decoder and adjust soft information for decoding subsequent codewords based on the bit error positions.

16. The receiver of claim 15, wherein the FEC decoder is configured to reduce log-likelihood ratio (LLR) absolute for bit positions close to the bit error positions and increase the LLR absolute for bit positions remote from the bit error positions.

17. A method for point-to-multi-point communications, comprising:
encoding input data to generate a plurality of codewords;
performing a combined processing of block or convolutional interleaving and codeword interleaving on the plurality of codewords to generate one or more interleaving blocks; and
generating a transmission frame based on the interleaving blocks and transmitting the transmission frame to a plurality of subscriber-side devices,
wherein each codeword belongs to one of a plurality of codeword groups associated with the plurality of subscriber-side devices and codewords belonging to different codeword groups are interleaved in each interleaving block.

18-19. (canceled)

20. The method of claim 17, wherein the number of the plurality of codeword groups is same as an interleaving depth, and each interleaving block contains bits from the same number of codewords as the interleaving depth.

21. The method of claim 17, wherein the number of the plurality of codeword groups is less than an interleaving depth, and each interleaving block contains bits from two or more codewords from a same codeword group.

22. The method of claim 17, wherein the number of the plurality of codeword groups is greater than an interleaving depth, and each interleaving block contains bits from a subset of the plurality of codeword groups.
